(19) United States
(12) Patent Application Publication
(10) Pub. No.: US 2010/0147571 A1
(43) Pub. Date: Jun. 17, 2010

(54) COMPONENT HAVING A METALIZED CERAMIC BASE

(76) Inventor: Claus Peter Kluge, Roslau (DE)

Correspondence Address: FULBRIGHT & JAWORSKI, LLP, 666 FIFTH AVE, NEW YORK, NY, 10103-3198, US

(21) Appl. No.: 12/596,875

(22) PCT Filed: Apr. 17, 2008
(86) PCT No.: PCT/EP08/54630

§ 371 Date: Oct. 21, 2009

(30) Foreign Application Priority Data
Apr. 24, 2007 (DE) 102007019632.8

(51) Int. Cl. H05K 1/02; B32B 7/02; B28B 11/00

(52) U.S. Cl. 174/259; 428/213; 264/232

(57) ABSTRACT

Components having a ceramic base the surface of which is covered in at least one area by a metalized coating, wherein the material on the surface of the ceramic base is chemically and/or crystallographically and/or physically modified with or without addition of suitable reactants across the entire surface or on partial surfaces of the metalized areas and forms at least one nonporous or porous layer, joined to the ceramic base, that has the same or different thickness of at least 0.001 nanometers, the layer containing at least one homogeneous or heterogeneous new material.

The invention relates to a component having a ceramic body, which is covered at at least one point of its surface with a metallized coating, and also to a method for the production of such a component.

A method for the production of a ceramic substrate with at least one layer of aluminium-nitride ceramic material and also the ceramic substrate that is produced according to this method are described in DE 196 03 822 C2. In order to increase the stability of the metallized coating, an auxiliary or intermediate layer of aluminium oxide is generated, for which the surface side that is intended to be metallized is provided with a layer of copper or of copper oxide or of other copper-containing compounds and is subsequently heat-treated in an atmosphere containing oxygen.

In the case of components that have a ceramic body covered at at least one point of its surface with a metallized coating, problems with the stability and the adhesive strength of the metallic coatings can arise.

The object of the invention consists in putting forward a component that has a ceramic body which is covered at at least one point of its surface with a metallized coating and is formed in a plate-shaped manner or is spatially structured and also a method for the production of such a component in which the metallized coating adheres particularly well.

The object is achieved with a component that has the characterising features of claim 1 and in accordance with the method with the aid of the characterising features of claim 19. Advantageous developments of the invention are put forward in the dependent claims.

The component in accordance with the invention consists of a ceramic body which is covered at at least one point of its surface with a metallized coating. The ceramic body is formed in a plate-shaped manner or is spatially structured. It can have an E-shape, for example. Heat sinks, for example, have such a form.

What is understood by a heat sink is a body which bears electrical or electronic structural elements or circuit arrangements and which is formed in such a way that it can dissipate the heat that develops in the structural elements or circuit arrangements in such a way that no accumulation of heat develops that can do damage to the structural elements or circuit arrangements. The carrier body is a body made from a material which electrically is not or is almost not conductive and has good thermal conductivity. The ideal material for such a body is ceramic material.

The body is in one piece and has heat-dissipating or heat-supplying elements to protect the electronic structural elements or circuit arrangements. The carrier body is preferably a printed circuit board, and the elements are bores, channels, ribs and/or clearances on which a heating or cooling medium can act. The medium can be liquid or gaseous. The carrier body and/or the cooling element preferably consist/consists of at least one ceramic component or a composite of different ceramic materials.

The ceramic material contains as a main component 50.1% by weight to 100% by weight ZrO₂/HfO₂ or 50.1% by weight to 100% by weight Al₂O₃ or 50.1% by weight to 100% by weight AlN or 50.1% by weight to 100% by weight Si₃N₄ or 50.1% by weight to 100% by weight BeO, 50:1% by weight to 100% by weight SiC or a combination of at least two of the main components in any combination in the specified range of proportions and also as a secondary component the elements Ca, Sr, Si, Mg, B, Y, Sc, Ce, Cu, Zn, Pb in at least one oxidation stage and/or compound with a proportion of ≦49.9% by weight individually or in any combination in the specified range of proportions. The main components and the secondary components, discounting a proportion of impurities of ≦3% by weight, can be combined with each other in any combination with each other to give a total composition of 100% by weight.

The metallized coating can, for example, consist of tungsten, silver, gold, copper, platinum, palladium, nickel, aluminium or steel of pure or industrial quality or of mixtures of at least two different metals. The metallized coating can, for example, also, additionally or solely, consist of reaction solders, soft solders or hard solders.

So that the metallized coating adheres well to the ceramic body of the component, the material at the surface of the ceramic body is modified over the whole or part of the surface by means of chemical or physical processes in a chemical and/or crystallographic and/or physical manner with or without the addition of suitable reactants. As a result, there develops on the ceramic body at that point or those points that have been treated at least one dense or porous layer that is connected to the ceramic body and has the same or different thickness of at least 0.001 nanometres and consists of at least one homogeneous or heterogeneous new material. The remaining base material of the ceramic body remains unchanged. At least one metallized coating can be connected to this new material over part of or the whole surface.

The reactants are substantially metals, such as copper or copper oxides in the case of the DCB (direct copper bonding) method or calcium compounds or manganese oxide or oxygen. Active metal components in the case of the AMB (active metal brazing) method are, for example, Zn, Sn, Ni, Pd, Ag, Cu, In, Zr, Ti, Ag, Yt, T, N.

By means of the method described above, a new material is generated on the surface of metal-oxide ceramic materials at least over the whole or part of the surface. A layer of intermetallic phases is formed with the aid of which metallized coatings can be put on ceramic bodies without the occurrence of blisters, flaking-off and other defects, in particular in the case of thermal loading.

The layer formed from the new material can, depending on the metallization, comprise a mixed layer which consists at least of aluminium oxide or copper oxides of different or the same oxidation stages or solid-state chemical mixtures thereof.

The layer formed can, depending on the metallization, comprise an intermediate layer which consists at least of aluminium oxide or copper oxides of different or the same oxidation stages or solid-state chemical mixtures thereof.

Combinations of at least one intermediate layer and at least one mixed layer are also possible.

In order to generate an intermediate layer of aluminium oxide, the surface of a ceramic body is provided over the whole or part of the surface with a layer of copper or of copper oxide or of other copper-containing compounds or combinations thereof to a minimum thickness of 0.001 nanometres and is subsequently treated in an oxygen-containing atmosphere at a temperature between 700° C. and 1380° C. for so long until the intermediate layer has formed with the desired thickness that can lie between 0.05 and 80 micrometers. The intermediate layer contains at least in one portion over its thickness a proportion of 0.01 to 80% by weight copper oxide.

When the aluminium nitride is treated with oxygen-containing atmosphere, at the same time a material containing copper oxide can be reacted, by way of the gas phase, with the aluminium oxide that is forming. The treatment in the oxygen-containing atmosphere with a proportion of vaporous copper oxide is effected for so long until a layer thickness of 0.05 to 80 micrometres has set in.

These intermediate layers, mixed layers or combinations of these layers render possible a connection between the ceramic material and the metallized coating that has adhesive strength. In particular in the case of the metallized coating with copper, the copper oxide of overlaid copper foils melts thereon and with the layer formed forms a defect-free, particularly stable connection.

The composition of at least one layer or intermediate layer or mixed layer is a homogeneous or graduated one, and at least one graduation points in one or more directions. Thus in one graduated layer the concentration of aluminium oxide can rise towards the aluminium nitride of the ceramic body, or the concentration of a mixed phase of proportions of copper oxides of different or the same oxidation stages with aluminium oxide can decrease towards the aluminium-oxide layer. As a result, it is possible to match the composition of the intermediate or mixed layer to the intended metallized coating.

At least one further metallized coating that is the same or different can be applied to the whole or part of the surface of a metallized coating, for example in order to produce soldered connections with electronic components.

After the treatment of the surface of the ceramic body, it is possible to secure a metallized coating using an oxidized metal or copper foil by means of the DCB method, a metal or copper layer, over the whole or part of the surface of at least one of the intermediate layers generated.

After the surface of the ceramic body has been treated, it is possible to secure a metallized coating using a metal foil by means of the AMB method, preferably of copper, aluminium or steel, over the whole or part of the surface of at least one of the intermediate layers generated.

At least the same or a different DCB substrate and/or a DCB-based circuit arrangement or at least the same or a different AMB substrate and/or an AMB-based circuit arrangement or at least a substrate-based circuit arrangement or printed circuit board or an active and/or a passive structural element and/or at least a sensory element can be connected to at least one metallized coating.

The invention is explained in greater detail with the aid of exemplary embodiments. In the drawings:

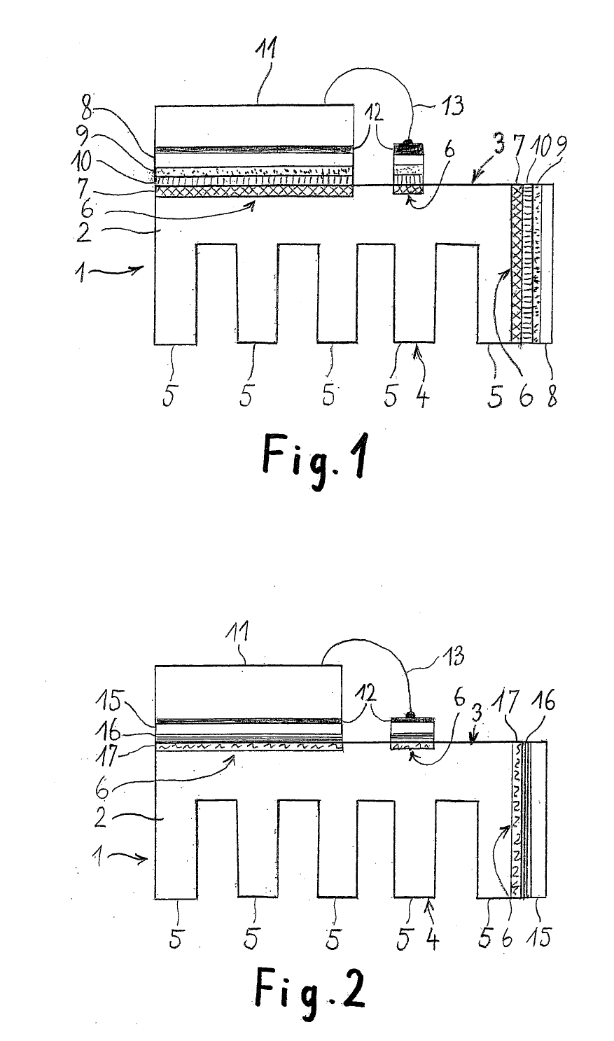

FIG. 1 shows a component in accordance with the invention which has been metallized according to the DCB method, with an electronic component;

FIG. 2 shows a component in accordance with the invention which has been metallized according to the AMB method, with an electronic component.

The component 1 in FIG. 1 has a ceramic body 2 made from aluminium nitride which is spatially structured; it is E-shaped. In the present exemplary embodiment, the body 2 is a heat sink. The upper side 3 and the lower side 4 of the ceramic body 2 each have surfaces of differing size. The lower side 4 has cooling ribs 5. The upper side 3 of the component 1 in the present exemplary embodiment has a planar surface. Metallized regions 6 onto which electronic components can be soldered, for example, are located on the upper side 3 and also on the leg of the outer cooling rib 5.

By means of the method in accordance with the invention, at the points 6 of the ceramic body 2 which are metallized, in the first instance an intermediate layer 7 of aluminium oxide is formed, to which the metallized coating is connected by way of further layers, a mixed layer. In the present exemplary embodiment, the metallization was effected according to the DCB method. The metallized coating 8 is a copper foil with a copper-oxide layer 9 which is connected to the intermediate layer 7 by way of a layer 10. Proportions of copper oxide and aluminium oxide are located in the layer 10.

The upper side 3 of the ceramic body 2 is a circuit-carrier. An electronic component, for example a chip 11, is secured on the metallized coating 8 on the upper side 3 by means of a soldered connection 12. It is connected to a further metallized region 6 by way of leads 13. This chip 11 represents a heat source, the heat of which is dissipated by way of the cooling ribs 7.

The component 1 in FIG. 2 has a ceramic body 2 which corresponds with that known from FIG. 1. Corresponding features are therefore provided with the same reference numerals. The ceramic body can consist, for example, of aluminium oxide, aluminium nitride, silicon nitride, zirconium oxides or carbides. It is spatially structured; it is E-shaped. In the present exemplary embodiment, the body 2 is likewise a heat sink. The upper side 3 and the lower side 4 of the ceramic body 2 each have surfaces of differing size. The lower side 4 has cooling ribs 5. The upper side 3 of the component 1 in the present exemplary embodiment has a planar surface. Metallized regions 6 onto which electronic components can be soldered, for example, are located on the upper side 3 and also on the leg of the outer cooling rib 5.

In the case of the present exemplary embodiment the metallization was effected by means of the AMB method. In this case, between the two portions that are to be connected, the ceramic body 2 and a metal foil as the metallized coating 15, for example of copper, aluminium or steel, there is poured a metallic filling material as a solder which contains active metallic additives which can react directly with the surface of the ceramic body 2. The alloys of the metallic filling material contain as active metal components Zn, Sn, Ni, Pd, Ag, Cu, In, Zr, Ti, Ag, Yt, T, N, for example. The remainder is formed by other alloying constituents. These alloys are preferably applied to the surface of the ceramic body in the form of a paste. The hard soldering (brazing) is preferably effected under vacuum or in an inert gas atmosphere of helium or argon.

During the hard-soldering, the metallic filling material that has been melted thereon, the solder 16, has formed, with the ceramic material of the ceramic body 2, a connection, a layer 17, in which the ceramic material has been modified. The metallized coating 15 is connected to the ceramic body 2 by way of this layer 17.

The upper side 3 of the ceramic body 2 is a circuit-carrier. An electronic component, for example a chip 11, is secured on the metallized coating 15 on the upper side 3 by means of a soldered connection 12. It is connected to a further metallized region 6 by way of leads 13. This chip 11 represents a heat source, the heat of which is dissipated by way of the cooling ribs 5.

1-37. (canceled)

38. A component having a ceramic body, which is covered at at least one point of its surface with a metallized coating, wherein the ceramic body is plate-shaped or spatially structured, in that the material at the surface of the ceramic body is modified over the whole or part of the surface by means of chemical or physical processes in a chemical or crystallographic or physical manner with or without the addition of suitable reactants and forms at least one dense or porous layer that is connected to the ceramic body with the same or a different thickness of at least 0.001 nanometers and consists of at least one homogeneous or heterogeneous new material, in that this new material is connected to at least one metallized coating over part of or the whole of the surface, and in that the remaining base material of the ceramic body is unchanged.

39. A component according to claim 38, wherein the ceramic material contains as a main component 50.1% by weight to 100% by weight ZrO₂/HfO₂ or 50.1% by weight to 100% by weight Al₂O₃ or 50.1% by weight to 100% by weight AlN or 50.1% by weight to 100% by weight Si₃N₄ or 50.1% by weight to 100% by weight BeO, 50.1% by weight to 100% by weight SiC or a combination of at least two of the main components in any combination in the specified range of proportions and also as a secondary component the elements Ca, Sr, Si, Mg, B, Y, Sc, Ce, Cu, Zn, Pb in at least one oxidation stage or compound with a proportion of ≦49.9% by weight individually or in any combination in the specified range of proportions, and in that the main components and the secondary components, discounting a proportion of impurities of ≦3% by weight, are combined with each other in any combination with each other to give a total composition of 100% by weight.

40. A component according to claim 38, wherein the metallized coating comprises tungsten, silver, gold, copper, platinum, palladium, nickel, aluminum or steel of pure or industrial quality or of mixtures of at least two different metals or, additionally or solely, of reaction solders, soft solders or hard solders.

41. A component according to claim 38, wherein the reactants for the formation of the layer of the new material are calcium compounds or manganese oxide or oxygen.

42. A component according to claim 38, wherein in the case of the DCB method the reactants for the formation of the layer of the new material are substantially metals such as copper or copper oxides.

43. A component according to claim 38, wherein in the case of the AMB method the reactants for the formation of the layer of the new material are substantially active metal components of Zn, Sn, Ni, Pd, Ag, Cu, In, Zr, Ti, Ag, Yt, T, N.

44. A component according to claim 38, wherein the layer that is formed from the new material comprises a mixed layer which consists at least of aluminum oxide or copper oxides of different or the same oxidation stages or solid-state chemical mixtures thereof.

45. A component according to claim 38, wherein the layer that is formed from the new material comprises an intermediate layer which consists at least of aluminum oxide or of copper oxides of different or the same oxidation stages or solid-state chemical mixtures thereof.

46. A component according to claim 38, wherein in order to generate an intermediate layer of aluminum oxide, an area of the ceramic body is provided with a layer of copper or of copper oxide or of other copper-containing compounds or combinations thereof with a minimum thickness of 0.001 nanometers.

47. A component according to claim 38, wherein the intermediate layer has a layer thickness of 0.05 to 80 micrometers.

48. A component according to claim 38, wherein in the intermediate layer at least in one portion over its thickness the proportion of copper oxide is between 0.01 and 80% by weight.

49. A component according to claim 38, wherein combinations of at least one intermediate layer and at least one mixed layer are present.

50. A component according to claim 38, wherein the composition of at least one layer or intermediate layer or mixed layer is a homogeneous or graduated one, and at least one graduation points in one or more directions.

51. A component according to claim 38, wherein in a graduated layer the concentration of aluminum oxide rises towards the aluminum nitride of the ceramic body.

52. A component according to claim 38, wherein the concentration of a mixed phase of proportions of copper oxides of different or the same oxidation stages with aluminum oxide decreases towards the aluminum-oxide layer.

53. A component according to claim 38, wherein a further metallized coating that is the same or different is applied over the whole or part of the surface of a metallized coating.

54. A component according to claim 38, wherein at least the same or a different DCB substrate or a DCB-based circuit arrangement or at least the same or a different AMB substrate or an AMB-based circuit arrangement or at least a substrate-based circuit arrangement or printed circuit board or an active or a passive structural element or at least a sensory element is connected to at least one metallized coating.

55. A component according to claim 38, wherein the ceramic body is a ceramic heat sink.

56. A method for producing a component having a ceramic body, which is covered at at least one point of its surface with a metallized coating according to claim 38, wherein the ceramic body is formed in a plate-shaped manner or is spatially structured, wherein the material at the surface of the ceramic body is modified over the whole or part of the surface by means of chemical or physical processes in a chemical or crystallographic or physical manner with or without the addition of suitable reactants and as a result there is formed at least one dense or porous layer that is connected to the ceramic body with the same or a different thickness of at least 0.01 nanometers and consists of at least one homogeneous or heterogeneous new material, wherein this new material is connected to at least one metallized coating over part of or the whole of the surface, and wherein the remaining base material of the ceramic body is not changed.

57. A method according to claim 56, wherein the ceramic material is composed of a main component of 50.1% by weight to 100% by weight ZrO₂/HfO₂ or 50.1% by weight to 100% by weight Al₂O₃ or 50.1% by weight to 100% by weight AlN or 50.1% by weight to 100% by weight Si₃N₄ or 50.1% by weight to 100% by weight BeO, 50.1% by weight to 100% by weight SiC or of a combination of at least two of the main components in any combination in the specified range of proportions and also of at least one secondary component of the elements Ca, Sr, Si, Mg, B, Y, Sc, Ce, Cu, Zn, Pb in at least one oxidation stage or compound with a proportion of ≦49.9% by weight individually or in any combination in the specified range of proportions, and in that the main components and the secondary components, discounting a proportion of impurities of ≦3% by weight, are combined with each other in any combination with each other to give a total composition of 100% by weight.

58. A method according to claim 56, wherein the metallization of the ceramic body of the component is preferably carried out with tungsten, silver, gold, copper, platinum, palladium, nickel, aluminum or steel of pure or industrial quality or of mixtures of at least two different metals or, additionally or merely, with reaction solders, soft solders or hard solders.

59. A method according to claim 56, wherein calcium compounds or manganese oxide or oxygen act as the reactants for the formation of the layer of the new material.

60. A method according to claim 56, wherein in the case of the DCB method substantially metals, such as copper or copper oxides, act as the reactants for the formation of the layer of the new material.

61. A method according to claim 56, wherein in the case of the AMB method substantially the active metal components of Zn, Sn, Ni, Pd, Ag, Cu, In, Zr, Ti, Ag, Yt, T, N act as the reactants for the formation of the layer of the new material.

62. A method according to claim 56, wherein the layer that is formed from the new material comprises a mixed layer which is formed at least from aluminum oxide or from copper oxides of different or the same oxidation stages or solid-state chemical mixtures thereof.

63. A method according to claim 56, wherein the layer that is formed from the new material comprises an intermediate layer which is formed at least from aluminum oxide or from copper oxides of different or the same oxidation stages or solid-state chemical mixtures thereof.

64. A method according to claim 56, wherein combinations of at least one intermediate layer and at least one mixed layer are generated.

65. A method according to claim 56, wherein at least one intermediate layer of aluminum oxide is generated on the surface of a ceramic body of aluminum nitride at least over the whole or part of the surface, for which purpose these areas are provided with a layer of copper or of copper oxide or of other copper-containing compounds or combinations thereof with a minimum thickness of 0.001 nanometers and are subsequently heat-treated in an oxygen-containing atmosphere.

66. A method according to claim 65, wherein the heat treatment is effected at a temperature between 700° C. and 1380° C.

67. A method according to claim 65, wherein, the treatment of the aluminum nitride is effected in the oxygen-containing atmosphere for sufficiently long for a layer thickness of 0.05 to 80 micrometers to set in for the respective intermediate layer.

68. A method according to claim 56, wherein when the aluminum nitride is treated with oxygen-containing atmosphere, at the same time a material containing copper oxide is reacted, by way of the gas phase, with the aluminum oxide that is forming.

69. A method according to claim 56, wherein the treatment in the oxygen-containing atmosphere with a proportion of vaporous copper oxide is effected for so long until a layer of aluminum oxide with a thickness of 0.05 to 80 micrometers has set in.

70. A method according to claim 56, wherein a proportion of copper oxide between 0.01 and 80% by weight is generated in the intermediate layer at least in one portion over its thickness.

71. A method according to claim 56, wherein after the treatment of the surface of a ceramic body on the at least one intermediate layer that has been generated a metallized coating is secured over an area using an oxidized metal or copper foil by means of the DCB A method.

72. A method according to claim 56, wherein after the treatment of the surface of a ceramic body of aluminum nitride at least one intermediate layer is generated, and in that a metal or copper layer is put on the at least one intermediate layer using the DCB method.

73. A method according to claim 56, wherein after the treatment of the surface of a ceramic body on the at least one intermediate layer that has been generated a metallized coating is secured over an area using a metal foil, preferably of copper, aluminum or steel, by means of the AMB method.

74. A method according to claim 56, wherein after the treatment of the surface of a ceramic body at least one intermediate layer is generated, and in that a metal foil, preferably of copper, aluminum or steel, is put on the at least one intermediate layer using the AMB method.
